(19) United States
(12) Patent Application Publication
(10) Pub. No.: US 2021/0343746 A1
(43) Pub. Date: Nov. 4, 2021

(54) DISPLAY PANEL AND DISPLAY DEVICE

(71) Applicants: HKC CORPORATION LIMITED, Shenzhen (CN); CHONGQING HKC OPTOELECTRONICS TECHNOLOGY CO., LTD., Chongqing (CN)

(72) Inventor: PEI HSIN LIN, Chongqing (CN)

(21) Appl. No.: 16/338,999

(22) PCT Filed: Nov. 8, 2018
(86) PCT No.: PCT/CN2018/114482

§ 371 Date: Apr. 3, 2019

(30) Foreign Application Priority Data
Sep. 30, 2018 (CN) 201821620338.7

(51) Int. Cl. H01L 27/12

(52) U.S. Cl. CPC H01L 27/124

(57) ABSTRACT

The present application discloses a display panel and a display device. A non-display region of the display panel includes fan-out regions, and the fan-out regions are regions constituted by all first metal lines connected to each sub-source drive circuit and regions constituted by all second metal lines connected to each sub-gate drive circuit; and barriers are disposed between the fan-out regions.

The present application claims the priority to the Chinese Patent Application No. CN201821620338.7, filed to the National Intellectual Property Administration, PRC on Sep. 30, 2018, and entitled “DISPLAY PANEL AND DISPLAY DEVICE”, which is incorporated herein by reference in its entirety.

### TECHNICAL FIELD

The present application relates to the field of display technologies, and particularly, to a display panel and a display device.

### BACKGROUND

The description herein merely provides background information related to the present application and does not necessarily constitute prior art.

With the development and advancement of science and technology, liquid crystal displays (LCD) are widely applied due to its advantages in thin body, low power consumption, no radiation, and on the like. Most LCDs on the market are backlight-type LCDs, each including a liquid crystal panel and a backlight module. The liquid crystal panel includes a color filter (CF) substrate and a thin film transistor (TFR) substrate, and a transparent electrode exists on an inner side relative to the CF substrate and the TFR substrate. A layer of liquid crystal (LC) molecules is sandwiched between the two substrates.

Polyimide covers a display region of the liquid crystal panel, so that the liquid crystal has good alignment. Coating quality of the polyimide directly affects an alignment angle of liquid crystal. Therefore, coating precision of the polyimide and how to effectively control a coating location of the polyimide are very important.

The inventor has learned that during the coating, the polyimide may overflow from the display region of the liquid crystal panel.

### SUMMARY

An object of the present application is to provide a display panel and a display device, to prevent polyimide from overflowing from a display region.

To achieve the forgoing object, the present application provides a display panel, including: a display region, including a plurality of data lines and a plurality of scan lines, a non-display region, surrounding the display region and including a plurality of first metal lines and a plurality of second metal lines, where one end of each first metal line is connected to one corresponding data line and one end of each second metal line is connected to one corresponding scan line; a source drive circuit, connected to the other end of each first metal line and including a plurality of sub-source drive circuits; and a gate drive circuit, connected to the other end of each second metal line and including a plurality of sub-gate drive circuits, where the non-display region includes a plurality of fan-out regions, the fan-out regions are regions constituted by all first metal lines connected to each of the sub-source drive circuits and regions constituted by all second metal lines connected to each of the sub-gate drive circuits, and barriers are between the fan-out regions.

Optionally, a material of the barriers is the same as materials of the first metal lines and second metal lines, and the barriers are disposed at a same layer as the first metal lines or second metal lines in adjacent fan-out regions.

Optionally, the first metal lines and the data lines are disposed at a same layer, the second metal lines and the scan lines are disposed at a same layer, and the fast metal lines and the second metal lines are disposed at different layers.

Optionally, the first metal lines and the second metal lines are both disposed at a same layer as a higher one of the data lines and the scan lines.

Optionally, the barriers include first barriers, the first barriers are disposed between adjacent fan-out regions, and each first barrier includes a first rim, a second rim, and a vertex angle, where the first rim and the second rim are in parallel to edges of adjacent fan-out regions, the vertex angle is an intersecting portion between the first rim and the second rim, and the vertex angle is close to the data lines or the scanlines.

Optionally, each first barrier includes third rims, the third rims are disposed between the first rim and the second rim, two ends of the third rims are respectively connected to the first rim and the second rim, and the third rims are perpendicular to the data lines or the scan lines.

Optionally, each first barrier includes a plurality of third rims, and any two of the third rims are disposed in parallel.

Optionally, a material of the barriers is an insulating material, and the barriers abut against edges of the adjacent fan-out regions.

Optionally the barriers include second barriers, the second barriers are adjacent to fan-out regions close to four corners of the display region, each second barrier includes a fourth rim and a fifth rim, the fourth rim is parallel to an edge of an adjacent fan-out region, and the fifth rim is parallel to the data lines or the scan lines.

Optionally, each second barrier includes sixth rims, the sixth rims are disposed between the fourth rim and the fifth rim, two ends of the six rims are respectively connected to the fourth rim and the fifth rim, and the sixth rims are perpendicular to the fifth rim.

Optionally, each second barrier includes a plurality of sixth rims, and any two of the sixth rims are disposed in parallel.

Each second barrier includes the plurality of sixth rims, to block splashing polyimide for multiple times. In addition, a larger area can be blocked by the parallel sixth rims.

The present application further discloses a display panel. The display panel includes: a display region, including a plurality of data lines and a plurality of scan lines; a non-display region, surrounding the display region and including a plurality of first metal lines and a plurality of second metal lines, where one end of each first metal line is connected to one corresponding data line, and one end of each second metal line is connected to one corresponding scan line; a source drive circuit, connected to the other end of each first metal line and including a plurality of sub-source drive circuits; and a gate drive circuit, connected to the other end of each second metal line and including a plurality of sub-gate drive circuits.

The non-display region includes a plurality of fan-out regions, and the fan-out regions are regions constituted by all first metal lines connected to each of the sub-source drive circuits and regions constituted by all second metal lines connected to each of the sub-gate drive circuits; barriers are disposed between the fan-out regions; a material of the barriers is the same as materials of the first metal lines and second metal lines, and the barriers are disposed at a same layer as the first metal lines or second metal lines in adjacent fan-out regions; the barriers include first barriers, the first barriers are disposed between adjacent fan-out regions, and each first barrier includes a first rim, a second rim, and a vertex angle, where the first rim and the second rim are parallel to edges of the adjacent fan-out regions, the vertex angle is an intersecting portion between the first rim and the second rim, and the vertex angle is close to the data lines or the scan lines.

Each first barrier includes third rims, the third rims are disposed between the first rim and the second rim, two ends of the third rims are respectively connected to the first rim and the second rim, and the third rims are perpendicular to the data lines or the scan lines; and each first barrier includes a plurality of third rims, and any two of the third rims are disposed in parallel.

The present application further discloses a display device. The display device includes the foregoing display panel.

Compared with a technology that no barrier is disposed between fan-out regions, in the present application, the barriers are added between the fan-out regions, so that when the polyimide overflows from the display region, the barriers between the fan-out regions block the overflowing polyimide. Therefore, the polyimide is better concentrated towards the display region, to provide a good alignment effect for liquid crystal, facilitating better image display.

### BRIEF DESCRIPTION OF DRAWINGS

The drawings are included to provide understanding of embodiments of the present application, which constitute a part of the specification and illustrate the embodiments of the present application, and describe the principles of the present application together with the text description. Apparently, the accompanying drawings in the following description show merely some embodiments of the present application, and a person of ordinary skill in the art may still derive other accompanying drawings from these accompanying drawings without creative efforts. In the accompanying drawings:

FIG. 1 is a schematic diagram of architecture of a chip-on-film display;

FIG. 2 is a schematic diagram of architecture of a liquid crystal display module;

FIG. 3 is a schematic diagram of architecture of a chip-on-film display in which polyimide overflows from a display region;

FIG. 4 is a schematic diagram of a first metal line and a second metal line in a fan-out region;

FIG. 5 is a schematic diagram of a data line fan-out region and a scan line fan-out region;

FIG. 6 is a schematic diagram of terrain of first metal lines in a data line fan-out region and terrain of second metal lines in a scan line fan-out regions;

FIG. 7 is a schematic diagram of architecture of an improved chip-on-film display according to an embodiment of the present invention;

FIG. 8 is a schematic diagram of a first barrier according to an embodiment of the present application; and

FIG. 9 is a schematic diagram of a second barrier according to an embodiment of the present application.

### DETAILED DESCRIPTION

The specific structure and function details disclosed herein are merely representative, and are intended to describe exemplary embodiments of the present application. However, the present application can be specifically embodied in many alternative forms, and should not be interpreted to be limited to the embodiments described herein.

In the description of the present application, it should be understood that, orientation or position relationships indicated by the terms “center”, “transversal”, “upper”, “lower”, “left”, “right”. “vertical”, “horizontal”, “top”, “bottom”, “inner”, “outer”, etc. are based on the orientation or position relationships as shown in the drawings, for ease of the description of the present application and simplifying the description only, rather than indicating or implying that the indicated device or element must have a particular orientation or be constructed and operated in a particular orientation. Therefore, these terms should not be understood as a limitation to the present application. In addition, the terms such as “first” and “second” are merely for a descriptive purpose, and cannot be understood as indicating or implying a relative importance, or implicitly indicating the number of the indicated technical features. Hence, the features defined by “first” and “second” can explicitly or implicitly include one or more features. In the description of the present application, “a plurality of” means two or more, unless otherwise stated. In addition, the term “include” and any variations thereof are intended to cover a non-exclusive inclusion.

In the description of the present application, it should be understood that, unless otherwise specified and defined, the terms “install”, “connected with”, “connected to” should be comprehended in a broad sense. For example, these terms may be comprehended as being fixedly connected, detachably connected or integrally connected; mechanically connected or coupled; or directly connected or indirectly connected through an intermediate medium or in an internal communication between two elements.

The specific meanings about the foregoing terms in the present application may be understood by those skilled in the art according to specific circumstances. The terms used herein are merely for the purpose of describing the specific embodiments, and are not intended to limit the exemplary embodiments. As used herein, the singular forms “a”, “an” are intended to include the plural forms as well, unless otherwise indicated in the context clearly. It will be further understood that the terms “comprise” and/or “include” used herein specify the presence of the stated features, integers, steps, operations, elements and/or components, but do not preclude the presence or addition of one or more other features, integers, steps, operations, elements, components and/or combinations thereof.

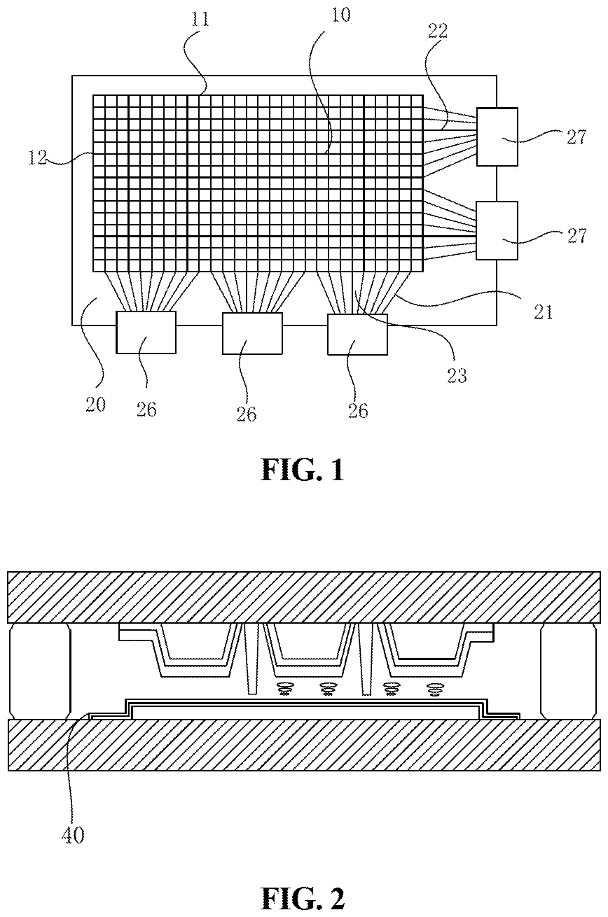

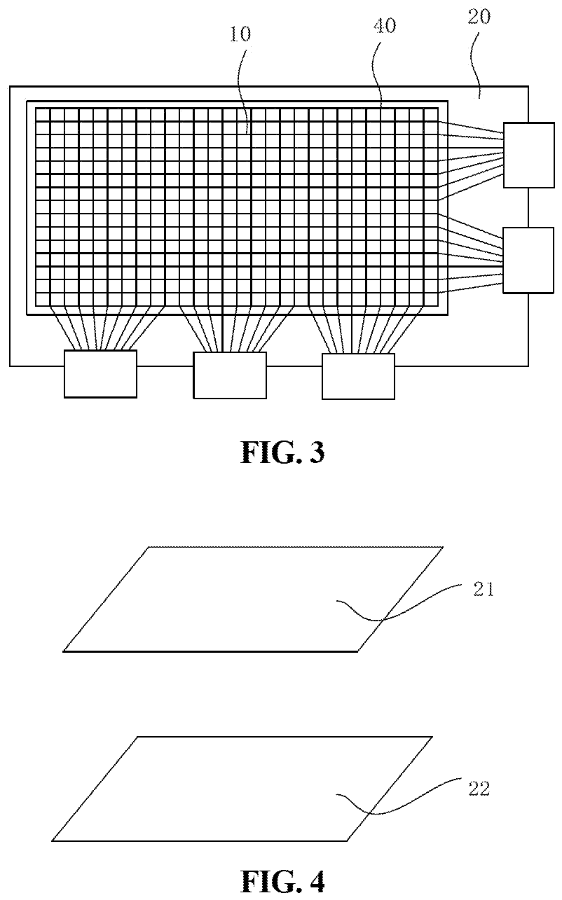

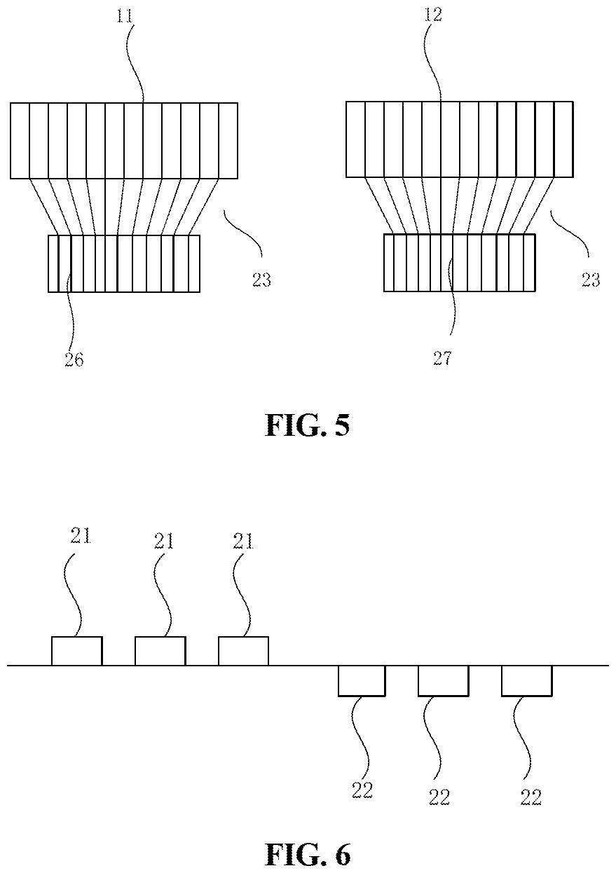

As shown in FIG. 1 to FIG. 6, in a chip-on-film display panel, a height of first metal lines 21 connecting data lines 11 to a data drive circuit 24 is inconsistent with a height of second metal lines 22 connecting scan lines 12 to a scan drive circuit 25, and the height of the second metal lines 12 is lower than the height of the fast metal lines 21. As a result, polyimide 40 easily overflows during coating.

The present application is described in detail below with reference to the accompanying drawings and optional embodiments.

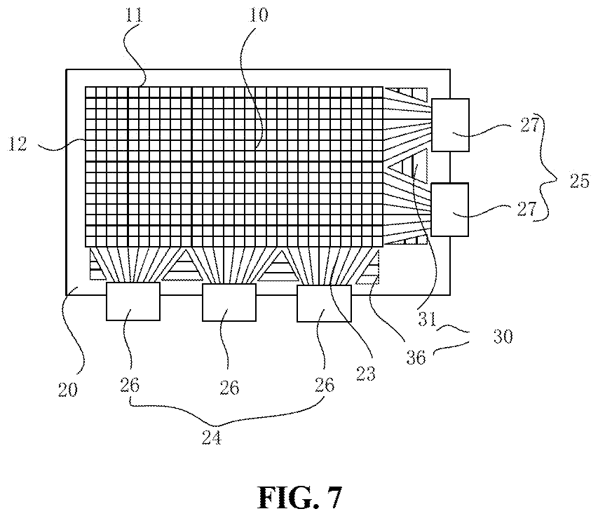

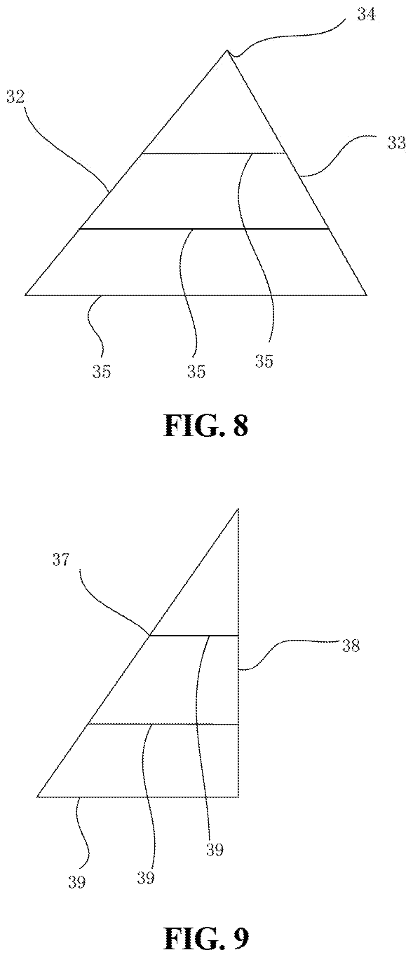

As shown in FIG. 7 to FIG. 9, an embodiment of the present application discloses a display panel. The display panel includes: a display region 10, including a plurality of data lines 11 and a plurality of scan lines 12; a non-display region 20, surrounding the display region 10 and including a plurality of first metal lines 21 and a plurality of second metal lines 22, where one end of each first metal line 21 is connected to one data line 11, and one end of each second metal line 22 is connected to one scan line 12; a source drive circuit 24, connected to the other end of each first metal line 21 and including a plurality of sub-source drive circuits 26; and a gate drive circuit 25, connected to the other end of each second metal line 22 and including a plurality of sub-gate drive circuits 27. The non-display region 20 includes a plurality of fan-out regions 23, and the fan-out regions 23 are regions constituted by all first metal lines 21 connected to each of the sub-source drive circuits 26 and regions constituted by all second metal lines 22 connected to each of the sub-gate drive circuits 27. Barriers 30 are disposed between the fan-out regions 23.

In the present application, the barriers 30 are disposed between the fan-out regions 23, so that after polyimide 40 overflows from the display region 10, the barriers 30 between the fan-out regions 23 block the overflowing polyimide 40. Therefore, the polyimide 40 is better concentrated towards the display region 10, to provide a good alignment effect for liquid crystal, facilitating better image display.

In an embodiment, a material of the barriers 30 is the same as materials of the first metal lines 21 and second metal lines 22, and the barriers 30 are disposed at a same layer as the first metal lines 21 or second metal lines 22 in adjacent fan-out regions 30.

In this solution, because the barriers 30 are made of the same material and disposed at the same layer as the adjacent first metal lines 21 or second metal lines 22, the barriers 30 may be manufactured together with the first metal lines 21 or second metal lines 22, thereby reducing one manufacturing process.

In an embodiment, the first metal lines 21 and the data lines 11 are disposed at a same layer, the second metal lines 22 and the scan lines 12 are disposed at a same layer, and the first metal lines 11 and the second metal lines 12 are disposed at different layers.

In this solution, when the data lines 11 or the scan lines 12 are manufactured on a substrate, the first metal lines 21 and the second metal lines 22 may be manufactured at the same time, so that a process for dedicatedly manufacturing the first metal lines 21 and the second metal lines 22 is reduced and time for manufacturing the display panel is reduced.

In an embodiment, the first metal lines 21 and the second metal lines 22 are both disposed at a same layer as a higher one of the data lines 11 and the scan lines 12.

In this solution, the first metal lines 21 and the second metal lines 22 are disposed at the same layer and have higher terrain, and the formed fan-out region 23 also has higher terrain, so that the polyimide 40 overflowing from the display region 10 is better blocked.

In an embodiment, the barriers 30 include first barriers 31, the first barriers 31 are disposed between adjacent fan-out regions 23, and each first barrier 31 includes a first rim 32, a second rim 33, and a vertex angle 34. The first rim 32 and the second rim 33 are parallel to edges of the adjacent fan-out regions 23, the vertex angle 34 is an intersecting portion between the first rim 32 and the second rim 33, and the vertex angle 34 is close to the data lines 11 or the scan lines 12.

In this solution, gaps between the barriers 30 and the first metal lines 21 or second metal lines 22 in the fan-out regions 23 can be reduced as much as possible when a short circuit is prevented from occurring between the barriers and the first metal lines 21 or the second metal lines 22, to block more alignment fluid 40.

In an embodiment, each first barrier 31 includes third rims 35, the third rims 35 are disposed between the first rim 32 and the second rim 33, two ends of the third rims are respectively connected to the first rim 32 and the second rim 33, and the third rims 35 are perpendicular to the data lines 11 or the scan lines 12.

In this solution, when the polyimide 40 impacts the vertex angle 34 of the first barrier 31, some of the polyimide 40 may splash out and pass through the first rim 32 and the second rim 33. If the third rims 35 are used to seal the first rim 32 and the second rim 33, the splashing polyimide 40 can be blocked within a region surrounded by the three rims and therefore prevented from flowing to the other part of the m-display region 20.

In an embodiment, each first barrier 31 includes a plurality of third rims 35, and any two of the third rims 35 are disposed in parallel.

In this solution, each first barrier 31 includes the plurality of third rims 35, to block the splashing polyimide 40 for multiple times. In addition, a larger area can be blocked by the parallel third rims.

In an embodiment, a material of the barriers 30 is an insulating material, and the barriers 30 abut against edges of the adjacent fan-out regions 23.

In this solution, because the barriers 30 are made of the insulating material, no short circuit occurs between the barriers 30 and the first metal lines 21 and the second metal lines 22. Consequently, the barriers 30 can be disposed closely to the fan-out region 23 to prevent the polyimide 40 from flowing out of the gaps between the barriers 30 and the sector.

In an embodiment, the barriers 30 include second barriers 36, and the second barriers 36 are adjacent to fan-out regions 23 close to four corners of the display region 10. Each second barrier 36 includes a fourth rim 37 and a fifth rim 38, the fourth rim 37 is parallel to an edge of an adjacent fan-out region 23, and the fifth rim 38 is parallel to the data lines 11 or the scan lines 12.

In this solution, gaps between the second barriers 36 and the first metal lines 21 or second metal lines 22 can be reduced as much as possible when a short circuit is prevented from occurring between the second barriers 36 and the first metal lines 21 or second metal lines 22 in the fan-out regions 23, so that when the polyimide 40 overflows from the corners of the display region 10, the polyimide 40 passing through the gaps between the second barriers 36 and the fan-out regions 23 is reduced. The fifth rim 38 has no adjacent fan-out region 23 and therefore has no function of blocking the polyimide 40. Therefore, the fifth rim 38 is disposed in parallel with the data lines 11 or the scan lines 12, so that a region surrounded by the fifth rim 38 and the fourth rim 37 has a relatively small area, thereby reducing materials.

In an embodiment, each second barrier 36 includes sixth rims 39 disposed between the fourth rim 37 and the fifth rim 38, two ends of the sixth rims are respectively connected to the fourth rim 37 and the fifth rim 38, and the sixth rims 39 are perpendicular to the fifth rim 38.

In this solution, when the polyimide 40 impacts the second barrier 36, some of the polyimide 40 may splash out and pass through the fourth rim 37 and the fifth rim 38. If the sixth rims 39 are used to seal the first rim 37 and the second rim 38, the splashing polyimide 40 can be blocked within a region surrounded by the three rims and therefore prevented from flowing to the other part of the non-display region 20.

In an embodiment, each second barrier 36 includes a plurality of sixth rims 39, and any two of the sixth rims 39 are disposed in parallel.

In this solution, each second barrier 36 includes the plurality of sixth rims 39, to block the splashing polyimide for multiple times. In addition, a larger area can be blocked by the parallel third rims.

As shown in FIG. 7 to FIG. 9, another embodiment of the present application discloses a display panel. The display panel includes: a display region 10, including a plurality of data lines 11 and a plurality of scan lines 12; a non-display region 20, surrounding the display region 10 and including a plurality of first metal lines 21 and a plurality of second metal lines 22, where one end of each first metal line 21 is connected to one data line 11, and one end of each second metal line 22 is connected to one scan line 12; a source drive circuit 24, connected to the other end of each first metal line 21 and including a plurality of sub-source drive circuits 26; and a gate drive circuit 25, connected to the other end of each second metal line 22 and including a plurality of sub-gate drive circuits 27. The non-display region 20 includes a plurality of fan-out regions 23, the fain-out regions 23 are regions constituted by all first metal lines 21 connected to each of the sub-source drive circuits 26 and regions constituted by all second metal lines 11 connected to each of the sub-gate drive circuits 27, and barriers 30 are disposed between the fa-out regions 23.

A material of the barriers 30 is the same as materials of the first metal lines 21 and second metal lines 22, and the barriers 30 are disposed at a same layer as the first metal lines 21 or second metal lines 22 in adjacent fan-out regions 30.

Each barrier 30 includes first barriers 31, the first barriers 31 are disposed between adjacent fan-out regions 23, each first barrier 31 includes a first rim 32, a second rim 33, and a vertex angle 34, where the first rim 32 and the second rim 33 are parallel to edges of the adjacent fan-out regions 23, the vertex angle 34 is an intersecting portion between the first rim 32 and the second rim 33, and the vertex angle 34 is close to the data lines 11 or the scan lines 12.

Each first barrier 31 includes third rims 35, the third rims 35 are disposed between the first rim 32 and the second rim 33, two ends of the third rims are respectively connected to the first rim 32 and the second rim 33, and the third rims 35 are perpendicular to the data lines 11 or the scan lines 12.

Each first barrier 31 includes a plurality of third rims 35, and any two of the third rims 35 are disposed in parallel.

In the present application, the barriers 30 are added between the fan-out regions 23, so that when polyimide 40 overflows from the display region 10, the barriers 30 between the fan-out regions 23 block the overflowing polyimide 40. Therefore, the polyimide 40 is better concentrated towards the display region 10, to provide a good alignment effect for liquid crystal, facilitating better image display.

As shown in FIG. 7 to FIG. 9, another embodiment of the present application discloses a display device. The display device includes the foregoing display panel.

The technical solutions of the present application may be widely applied to various display panels, for example, a twisted nematic display panel, an in-plane switching display panel, a vertical alignment display panel, and a multi-domain vertical alignment display panel. Certainly, the solutions may also be applied to other types of display panels, for example, an organic light-emitting diode (OLED) display panel.

The foregoing is an optional detailed description of the present application with reference to specific preferred embodiments, and it should not be considered that the specific implementation of the present application is not limited to the description. A person of ordinary skill in the art of the present application may further make several simple deductions or substitutions without departing from the concept of the present application, and the deductions or substitutions shall fall within the protection scope of the present application.

What is claimed is:

1. A display panel, comprising:
a display region, comprising a plurality of data lines and a plurality of scan lines;
a non-display region, surrounding the display region and comprising a plurality of first metal lines and a plurality of second metal lines, wherein one end of each first metal line is connected to one corresponding data line, and one end of each second metal line is connected to one corresponding scan line;
a source drive circuit, connected to the other end of each first metal line and comprising a plurality of sub-source drive circuits; and
a gate drive circuit, connected to the other end of each second metal line and comprising a plurality of sub-gate drive circuits, wherein
the non-display region comprises a plurality of fan-out regions, and the fan-out regions are regions constituted by all first metal lines connected to each of the sub-source drive circuits and regions constituted by all second metal lines connected to each of the sub-gate drive circuits; and
barriers are disposed between the fan-out regions.

2. The display panel according to claim 1, wherein a material of the barriers is the same as materials of the first metal lines and second metal lines.

3. The display panel according to claim 1, wherein a material of the barriers is an insulating material, and the barriers abut against edges of adjacent fan-out regions.

4. The display panel according to claim 2, wherein the barriers are disposed at a same layer as the first metal lines or the second metal lines in adjacent fan-out regions.

5. The display panel according to claim 4, wherein the first metal lines and the data lines are disposed at a same layer, the second metal lines and the scan lines are disposed at a same layer, and the first metal lines and the second metal lines are disposed at different layers.

6. The display panel according to claim 4, wherein the first metal lines and the second metal lines are both disposed at a same layer as a higher one of the data lines and the scan lines.

7. The display panel according to claim 4, wherein the barriers comprise first barriers, the first barriers are disposed between adjacent fan-out regions, and each first barrier comprises a first rim, a second rim, and a vertex angle, wherein the first rim and the second rim are parallel to edges of the adjacent fan-out regions, the vertex angle is an intersecting portion between the first rim and the second rim, and the vertex angle is close to the data lines or the scan lies.

8. The display panel according to claim 7, wherein each first barrier comprises third rims, the third rims are disposed between the first rim and the second rim, two ends of the third rims are respectively connected to the first rim and the second rim, and the third rims are perpendicular to the data lines or the scan lines.

9. The display panel according to claim 8, wherein each first barrier comprises a plurality of third rims.

10. The display panel according to claim 9, wherein any two of the third rims are disposed in parallel.

11. The display panel according to claim 4, wherein the barriers comprise second barriers, the second barriers are adjacent to fan-out regions close to four corners of the display region, each second barrier comprises a fourth rim and a fifth rim, the fourth rim is parallel to an edge of an adjacent fan-out region, and the fifth rim is parallel to the data lines or the scan lines.

12. The display panel according to claim 11, wherein each second barrier comprises sixth rims, the sixth rims are disposed between the fourth rim and the fifth rim, two ends of the six rims are respectively connected to the fourth rim and the fifth rim, and the sixth rims are perpendicular to the fifth rim.

13. The display panel according to claim 12, wherein each second barrier comprises a plurality of sixth rims.

14. The display panel according to claim 13, wherein any two of the sixth rims are disposed in parallel.

15. A display panel, comprising:
a display region, comprising a plurality of data lines and a plurality of scan lines;
a non-display region, surrounding the display region and comprising a plurality of first metal lines and a plurality of second metal lines, wherein one end of each first metal line is connected to one corresponding data line, and one end of each second metal line is connected to one corresponding scan line;
a source drive circuit, connected to the other end of each first metal line and comprising a plurality of sub-source drive circuits; and
a gate drive circuit, connected to the other end of each second metal line and comprising a plurality of sub-gate drive circuits, wherein
the non-display region comprises a plurality of fan-out regions, and fan-out regions are regions constituted by all first metal lines connected to each of the sub-source drive circuits and regions constituted by all second metal lines connected to each of the sub-gate drive circuits;
barriers are disposed between the fan-out regions;
a material of the barriers is the same as materials of the first metal lines and second metal lines, and the barriers are disposed at a same layer as the first metal lines or second metal lines in adjacent fa-out regions;
the barriers comprise first barriers, the first barriers are disposed between adjacent fan-out regions, and each first barrier comprises a first rim, a second rim, and a vertex angle, wherein the first rim and the second rim are parallel to edges of the adjacent fan-out regions, the vertex angle is an intersecting portion between the first rim and the second rim, and the vertex angle is close to the data lines or the scan lines;
each first barrier comprises third rims, the third rims are disposed between the first rim and the second rim, two ends of the third rims are respectively connected to the first rim and the second rim, and the third rims are perpendicular to the data lines or the scan lines; and
each first barrier comprises a plurality of third rims, and any two of the third rims are disposed in parallel.

16. A display device, comprising a display panel, wherein the display panel comprises:
a display region, comprising a plurality of data lines and a plurality of scan lines;
a non-display region, surrounding the display region and comprising a plurality of first metal lines and a plurality of second metal lines, wherein one end of each first metal line is connected to one corresponding data line, and one end of each second metal line is connected to one corresponding scan line;
a source drive circuit, connected to the other end of each first metal line and comprising a plurality of sub-source drive circuits; and
a gate drive circuit, connected to the other end of each second metal line and comprising a plurality of sub-gate drive circuits, wherein
the non-display region comprises a plurality of fan-out regions, and the fan-out regions are regions constituted by all first metal lines connected to each of the sub-source drive circuits and regions constituted by all second metal lines connected to each of the sub-gate drive circuits; and
barriers are disposed between the fan-out regions.

17. The display device according to claim 16, wherein a material of the barriers is the same as materials of the first metal lines and second metal lines, and the barriers are disposed at a same layer as first metal lines or second metal lines in adjacent fan-out regions;
the barriers comprises first barriers, the first barriers are disposed between adjacent fan-out regions, and each first barrier comprises a first rim, a second rim, and a vertex angle, wherein the first rim and the second rim are parallel to edges of the adjacent fan-out regions, the vertex angle is an intersecting portion between the first rim and the second rim, and the vertex angle is close to the data lines or the scan lines; and
each first barrier comprises third rims, the third rim is disposed between the first rim and the second rim, two ends of the third rims are respectively connected to the first rim and the second rim, and the third rims are perpendicular to the data lines or the scan lines; and each first barrier comprises a plurality of third rims, and any two of the third rims are disposed in parallel.
